(19) United States
(12) Patent Application Publication
(10) Pub. No.: US 2025/0336429 A1
(43) Pub. Date: Oct. 30, 2025

(54) MEMORY DEVICE WHICH GENERATES OPTIMAL WRITE VOLTAGE BASED ON REFERENCE RESISTANCE OF MEMORY CELL AND METHOD OF OPERATING THE SAME

(71) Applicant: SAMSUNG ELECTRONICS CO., LTD., Suwon-si (KR)

(72) Inventor: Daeshik Kim, Suwon-si (KR)

(21) Appl. No.: 19/017,127

(22) Filed: Jan. 10, 2025

(30) Foreign Application Priority Data
Apr. 30, 2024 (KR) 10-2024-0057868

(51) Int. Cl. G11C 11/16

(52) U.S. Cl. CPC G11C 11/1675; G11C 11/1673; G11C 11/1677

(57) ABSTRACT

Disclosed is a memory device which includes a memory cell array that includes a first region and a second region, a voltage generator that generates a code value corresponding to a write voltage, and a write driver that stores data in the first region in response to the code value. The second region stores a value of the write voltage for programming at least one memory cell among a plurality of memory cells of the memory cell array and a value of a reference resistance for distinguishing a parallel state and an anti-parallel state of the at least one memory cell. The value of the write voltage is obtained based on an initial value of the write voltage corresponding to the value of the reference resistance and a final value of the write voltage obtained based on the value of the initial write voltage.

### CROSS-REFERENCE TO RELATED APPLICATION

This application claims priority under 35 U.S.C. § 119 to Korean Patent Application No. 10-2024-0057868 filed on Apr. 30, 2024, in the Korean Intellectual Property Office, the entirety of which is incorporated by reference herein.

### BACKGROUND

At present, various types of electronic devices are being used. As a high-speed and low-power electronic device is required, the electronic device may require a memory device satisfying high-reliability, high-speed, and low-power consumption characteristics. To satisfy the required characteristics, a magnetic memory element has been suggested as a memory element of the memory device. Because the magnetic memory element operates at a high speed and provides a nonvolatile characteristic, the magnetic memory element has been highlighted as a next-generation semiconductor memory element.

In general, the magnetic memory element may include a magnetic tunnel junction (MTJ) element. The MTJ element may include two magnetic materials and an insulating layer interposed therebetween. A resistance value of the MTJ element may vary depending on magnetization directions of two magnetic materials. For example, the MJT element may have a high resistance value when the magnetization directions of two magnetic materials are anti-parallel to each other and may have a small resistance value when the magnetization directions of two magnetic materials are parallel to each other. Data may be written or read by using a difference of the resistance values.

A reference resistance for reading data stored in the memory cell, that is, for distinguishing the parallel state and the anti-parallel state is used, and the read success or failure depends on a value of the reference resistance. However, optimal reference resistance values of memory chips may be different from each other due to sizes and characteristics of MTJ elements, a process deviation, etc. In addition, optimal reference resistance values may be different depending on local locations in one memory chip.

### SUMMARY

For purposes of this disclosure, it has been recognized that it can be important to use an optimal reference resistance value to improve the reliability of read operations using magnetic memories. Some aspects of the present disclosure provide memory devices including a magnetic tunnel junction element and implementing an optimal write voltage value capable of solving a write failure and an endurance issue.

Some aspects of the present disclosure provide operating methods of memory devices capable of reducing a time necessary to obtain an optimal write voltage.

According to some implementations, a memory device includes a memory cell array that includes a first region and a second region, a voltage generator that generates a code value corresponding to a write voltage, and a write driver that stores data in the first region in response to the code value. The second region stores a value of the write voltage for programming at least one memory cell among a plurality of memory cells of the memory cell array and a value of a reference resistance for distinguishing a parallel state and an anti-parallel state of the at least one memory cell. The value of the write voltage is obtained based on an initial value of the write voltage corresponding to the value of the reference resistance and a final value of the write voltage obtained based on the value of the initial write voltage.

According to some implementations, a method of operating a memory device which includes a plurality of memory cells includes programming the plurality of memory cells to a first state, counting fail bits of the memory cells programmed to the first state by using a plurality of resistances with different values and outputting first counting results, programming the plurality of memory cells to a second state, counting fail bits of the memory cells programmed to the second state by using the plurality of resistances and outputting second counting results, selecting a value of a reference resistance among the plurality of resistances, based on the first counting results and the second counting results, obtaining an initial value of a write voltage corresponding to the reference resistance, programming the plurality of memory cells to the first state by using the write voltage with the initial value, counting fail bits of the memory cells programmed to the first state by using the reference resistance and outputting third counting results, programming the plurality of memory cells to the first state by using a neighboring write voltage whose value is close to the initial value of the write voltage, counting fail bits of the memory cells programmed to the first state by using the reference resistance and outputting fourth counting results, and obtaining a final value of the write voltage based on the third counting result and the fourth counting result.

According to some implementations, a memory device includes a memory cell array that includes a first region and a second region, the first region including a cell string and a dummy cell string and the cell string including a plurality of memory cells each including a magnetic tunnel junction element, a voltage generator that generates a code value corresponding to a write voltage, a write driver that stores data in the memory cell array in response to the code value, a sense amplifier that includes a first input terminal to which a first end of the cell string is connected and a second input terminal to which a first end of the dummy cell string is connected through a reference resistance, and a current source circuit configured to provide input currents to the sense amplifier. The second region stores a value of the write voltage for programming at least one memory cell among a plurality of memory cells of the memory cell array and a value of a reference resistance for distinguishing a parallel state and an anti-parallel state of the at least one memory cell. The value of the write voltage is obtained based on an initial value of the write voltage corresponding to the value of the reference resistance and a final value of the write voltage obtained based on the value of the initial write voltage.

### BRIEF DESCRIPTION OF THE FIGURES

The above and other objects and features of the present disclosure will become apparent by describing in detail examples with reference to the accompanying drawings.

FIG. 1 illustrates an example of a substrate having integrated memory chips.

FIG. 2 illustrates an example of a configuration of a memory device associated with a memory chip of FIG. 1.

FIG. 3 is a circuit diagram illustrating an example of a configuration of a memory cell array of FIG. 2.

FIG. 4 is a circuit diagram illustrating an example of a configuration of a memory cell array of FIG. 2.

FIGS. 5 and 6 illustrate an example of a configuration of a memory cell of FIG. 3.

FIG. 7 is a diagram illustrating an example of a configuration associated with a memory cell of FIG. 3.

FIG. 8 illustrates examples of components associated with a pre-program or program operation from among components of a memory device of FIG. 2.

FIG. 9 illustrates examples of resistance distributions of pre-programmed or programmed memory cells.

FIG. 10 illustrates an example of a configuration associated with a read operation on the memory cell array 110 of FIG. 2.

FIG. 11 is a graph illustrating an example of determination a value of a global reference resistance for distinguishing a program state of a memory cell.

FIG. 12 is a diagram illustrating an example of determination of a value of a write voltage based on a reference resistance value determined in FIG. 11.

FIG. 13 is a graph illustrating an example of a correlation relationship between an MTJ resistance and a switching current of an MRAM cell.

FIG. 14 is a graph illustrating an example of obtaining an optimal write voltage value through fine trim.

FIG. 15 is a graph illustrating an example of obtaining an optimal write voltage value through fine trim.

FIG. 16 is a graph illustrating an example of obtaining an optimal write voltage value through fine trim.

FIG. 17 is a graph illustrating an example of obtaining an optimal write voltage value through fine trim.

FIG. 18 is a graph illustrating an example of obtaining an optimal write voltage value through fine trim.

FIG. 19 illustrates an example of a configuration associated with a read operation on a memory cell array of FIG. 2.

FIG. 20 illustrates an example of a configuration of a reference resistance of FIG. 11.

FIGS. 21 and 22 are examples of circuit diagrams associated with a pre-program operation or a program operation of a write driver of FIG. 8.

FIG. 23 is a flowchart illustrating an example of a test method of a memory device.

FIG. 24 is a flowchart illustrating an example of a test method of a memory device.

FIG. 25 is a block diagram illustrating an example of a test system for testing a memory device.

FIG. 26 is a diagram illustrating an example of a system to which the memory devices herein can be applied.

### DETAILED DESCRIPTION

In the following description, components which are described with reference to the terms “unit”, “module”, “block”, “˜er or ˜or”, etc. and function blocks which are illustrated in drawings can be implemented in the form of software or hardware or a combination thereof. For example, the software may include a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

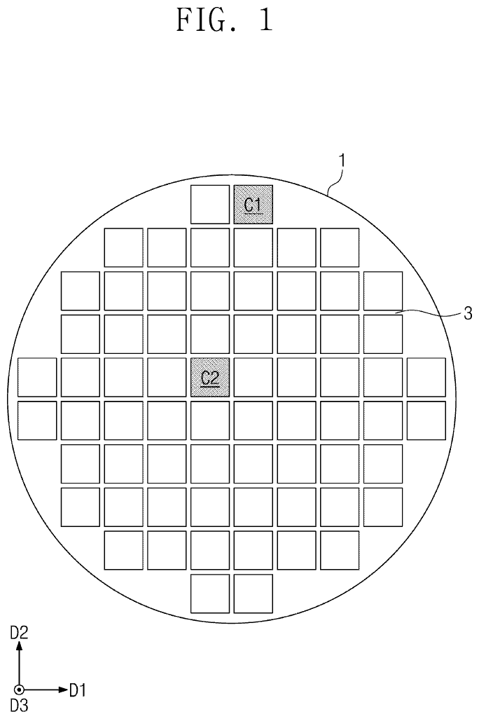

FIG. 1 illustrates a substrate 1 where memory chips are integrated, according to some implementations of the present disclosure. The substrate 1 may include a plurality of memory chips including a first memory chip C1 and a second memory chip C2, and a scribe line region 3 between the memory chips. The memory chips may be two-dimensionally arranged along a first direction D1 and a second direction D2. Each chip may be surrounded by the scribe line region 3. For example, the scribe line region 3 may be defined between memory chips adjacent in the first direction D1 and between memory chips adjacent in the second direction D2.

In some implementations, the substrate 1 is a semiconductor substrate such as a semiconductor wafer. The substrate 1 may be a bulk silicon substrate, a silicon on insulator (SOI) substrate, a germanium substrate, a germanium on insulator (GOI) substrate, a silicon-germanium substrate, or a substrate of an epitaxial thin film formed through selective epitaxial growth (SEG). For example, the substrate 1 may include at least one of silicon (Si), germanium (Ge), silicon germanium (SiGe), gallium arsenic (GaAs), indium gallium arsenide (InGaAs), aluminum gallium arsenide (AlGaAs), or a mixture thereof. The substrate 1 may have a single crystalline structure.

For example, the first memory chip C1 may represent a memory chip formed relatively at a periphery of the substrate 1, and the second memory chip C2 may represent a memory chip formed relatively at the center of the substrate 1.

A program characteristic of memory cells of a memory chip, such as a reference resistance characteristic, may vary depending on a location on the substrate 1 at which the memory chip is formed. For example, when the memory chips formed on the substrate 1 include MRAM cells, the size of the MRAM cell may vary depending on a location in the substrate 1 at which the memory device is formed.

For example, the size of the MRAM cell of the first memory chip Cl placed at an outer edge of the substrate 1 may be relatively small due to the manufacturing process. In contrast, the size of the MRAM cell of the second memory chip C2 placed on an inner portion of the substrate 1 may be relatively large due to the manufacturing process. Other relationships are also possible. For example, in some cases, due to the manufacturing process, the size of the MRAM cell of the first memory chip C1 may be relatively large, and the size of the MRAM cell of the second memory chip C2 may be relatively small.

In general, a value of an MTJ resistance of an MRAM cell with a relatively large size may be small, and a value of an MTJ resistance of an MRAM cell with a relatively small size may be large. A value of a reference resistance for determining a program state of an MRAM cell correlates with a value of the MTJ resistance. For example, as the value of the MTJ resistance of the MRAM cell becomes larger, the value of the reference resistance becomes larger, and, as the value of the MTJ resistance of the MRAM cell becomes smaller, the value of the reference resistance becomes smaller. Also, as the size of the MRAM cell becomes larger, a value of the program voltage (or switching current) of the MRAM cell may become larger. And, as the size of the MRAM cell becomes smaller, a value of the program voltage (or switching current) of the MRAM cell may become smaller.

However, even when MRAM cells have the same MTJ resistance value, there may be a variation in a value of the program voltage (or switching current) due to a process issue. Accordingly, to determine the value of the program voltage (or switching current) only in consideration of the reference resistance value may cause write failure and/or endurance issues due to the above variation. To at least partially remedy this problem, according to some implementations of the present disclosure, an initial value of the program voltage is determined by using a value of a reference resistance of a memory device (this is hereinafter referred to as “coarse trim”), and the value of the program voltage is determined finely around the initial program voltage value to apply the variation of the program voltage (or switching current) value (this is hereinafter referred to as “fine trim”).

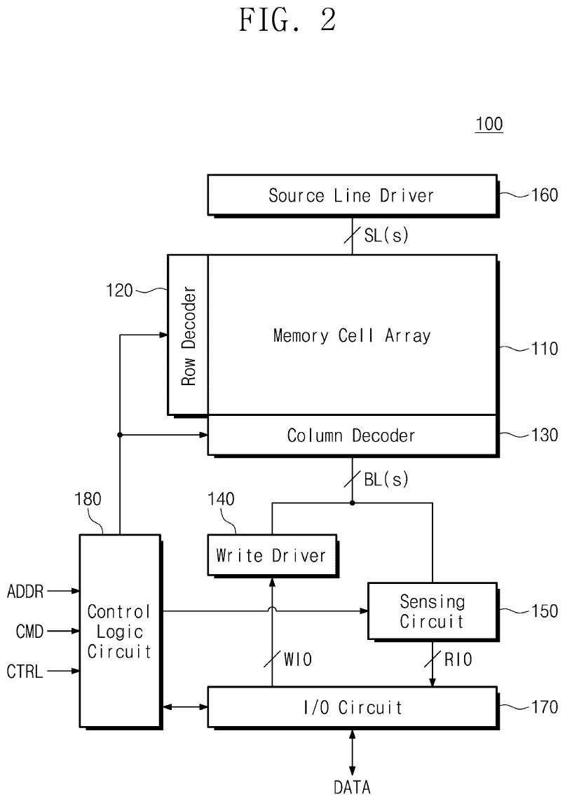

FIG. 2 illustrates a configuration of a memory device associated with the memory chips C1 and C2 of FIG. 1.

A memory device 100 may include a memory cell array 110, a row decoder 120, a column decoder 130, a write driver 140, a sensing circuit 150, a source line driver 160, an input/output circuit 170, and a control logic circuit 180. In some implementations, each of the memory chips C1 and C2 of FIG. 1 may include the memory cell array 110. However, the present disclosure is not limited thereto. For example, each of the memory chips C1 and C2 may further include one or more of the remaining components of the memory device 100, in addition to the memory cell array 110.

The memory cell array 110 may include a plurality of memory cells each configured to store data. For example, each memory cell may include a variable resistance element, and a value of data stored therein may be determined based on a resistance value of the variable resistance element. For example, each memory cell may include a magneto-resistive RAM (MRAM) cell, a spin transfer torque MRAM (STT-MRAM) cell, a spin-orbit torque MRAM (SOT-MRAM) cell, a phase-change RAM (PRAM) cell, a resistive RAM (ReRAM) cell, etc. In the specification, below, description will be given under the assumption that each memory cell includes an STT-MRAM cell.

The memory cells constituting the memory cell array 110 may be connected to source lines SL, bit lines BL, and word lines. For example, memory cells arranged along a row may be connected in common to a word line corresponding to the row, and memory cells arranged along a column may be connected in common to a source line and a bit line corresponding to the column.

The row decoder 120 may select (or drive) a word line connected to a memory cell targeted for the read operation or the program operation under control of the control logic circuit 180. The row decoder 120 may provide the selected word line with a driving voltage received from the control logic circuit 180.

The column decoder 130 may select the bit line BL and/or the source line SL connected to the memory cell targeted for the read operation or the program operation under control of the control logic circuit 180.

In the program operation, the write driver 140 may drive a program voltage (or a write current) for storing write data in a memory cell selected by the row decoder 120 and the column decoder 130. For example, in the program operation of the memory device 100, the write driver 140 may store the write data in the selected memory cell by controlling a voltage of a data line DL based on the write data provided from the input/output circuit 170 through a write input/output line WIO.

In the read operation, the sensing circuit 150 may sense a signal output through the bit line BL and may determine a value of data stored in the selected memory cell. The sensing circuit 150 may be connected to the column decoder 130 through the bit line BL and may be connected to the input/output circuit 170 through a read input/output line RIO. The sensing circuit 150 may output the sensed read data to the input/output circuit 170 through the read input/output line RIO.

The source line driver 160 may drive the source line SL to a target voltage level under control of the control logic circuit 180. For example, the source line driver 160 may be provided with a voltage for driving the source line SL from the control logic circuit 180. For example, a value of a voltage applied from the source line driver 160 to the source line SL when the program operation is performed such that a memory cell has a large resistance value (e.g., an anti-parallel state) may be different from a value of a voltage applied from the source line driver 160 to the source line SL when the program operation is performed such that a memory cell has a small resistance value (e.g., a parallel state).

In the program operation, the input/output circuit 170 may receive write data “DATA” from the outside and may provide the received write data to the write driver 140. In the read operation, the input/output circuit 170 may read data from the memory cell array 110 and may output the read data to the outside as read data “DATA”.

The control logic circuit 180 may receive a command CMD, an address ADDR, and a control signal CTRL from the outside. The control logic circuit 180 may control the components of the memory device 100, based on the command CMD, the address ADDR, and the control signal CTRL. For example, the control logic circuit 180 may control the row decoder 120 and the column decoder 130, and thus, a target memory cell on which the program operation or the read operation is to be performed may be selected.

In some implementations, the control logic circuit 180 controls a value of the reference resistance which is used to determine a program state of a memory cell, based on the control signal CTRL. The control signal CTRL may include information about an optimal value of the reference resistance which is used to determine a program state of a memory cell. The control signal CTRL may include a control signal for controlling the write driver 140 such that a program voltage (or switching current) of a desired level is generated.

The memory device 100 may further include a one-time programmable (OTP) memory. Information about the memory device 100 may be programmed in the OTP memory. In some implementations, information about a fail address of the memory cell array 110, information about internal voltages (e.g., a program voltage and a read voltage) of the memory device 100, etc. may be programmed in the OTP memory. According to some implementations of the present disclosure, an optimal reference resistance value, a program voltage (current) value, etc. which are determined in the process of testing a memory device may be programmed in the OTP memory.

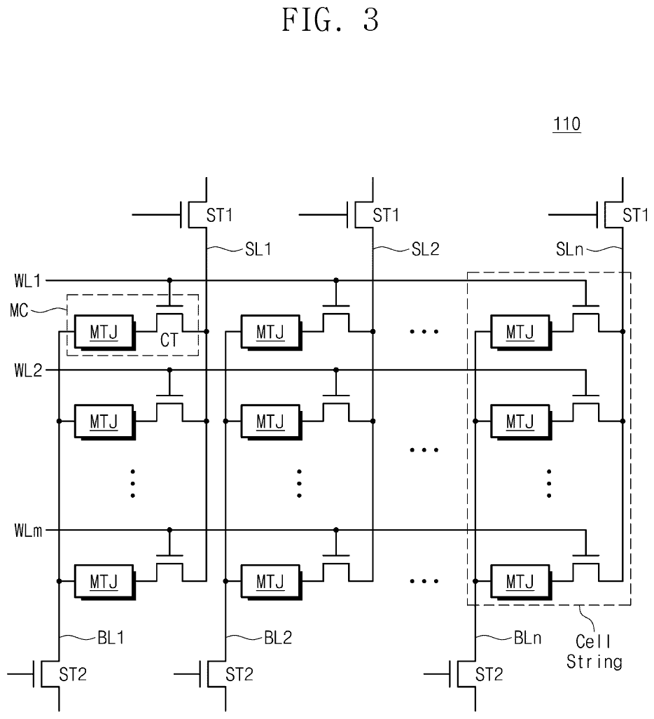

FIG. 3 is a circuit diagram illustrating a configuration of the memory cell array 110 of FIG. 2.

Select transistors ST1 and ST2 among components illustrated in FIG. 3 may constitute the column decoder 130 (refer to FIG. 2) and are illustrated together with the memory cell array 110 to represent the connection relationship with the memory cell array 110.

The memory cell array 110 may include a plurality of memory cells arranged along row and column directions. A memory cell MC may include a magnetic tunnel junction (MTJ) element and a cell transistor CT. As the MTJ element of the memory cell MC is programmed to have a specific resistance value, data corresponding to the specific resistance value may be stored in the memory cell MC. A cell string may include a plurality of memory cells which are connected in common to one bit line and one source line.

The plurality of memory cells may be connected to word lines WL1 to WLm, bit lines BL1 to BLn, and source lines SL1 to SLn. A first end of the MTJ element may be connected to the first bit line BL1, and a second end of the MTJ element may be connected to a first end of the cell transistor CT. A second end of the cell transistor CT may be connected to the first source line SL1, and a gate electrode of the cell transistor CT may be connected to the first word line WL1. The source lines SL1 to SLn may be respectively connected to the select transistors ST1, and the bit lines BL1 to BLn may be respectively connected to the select transistors ST2.

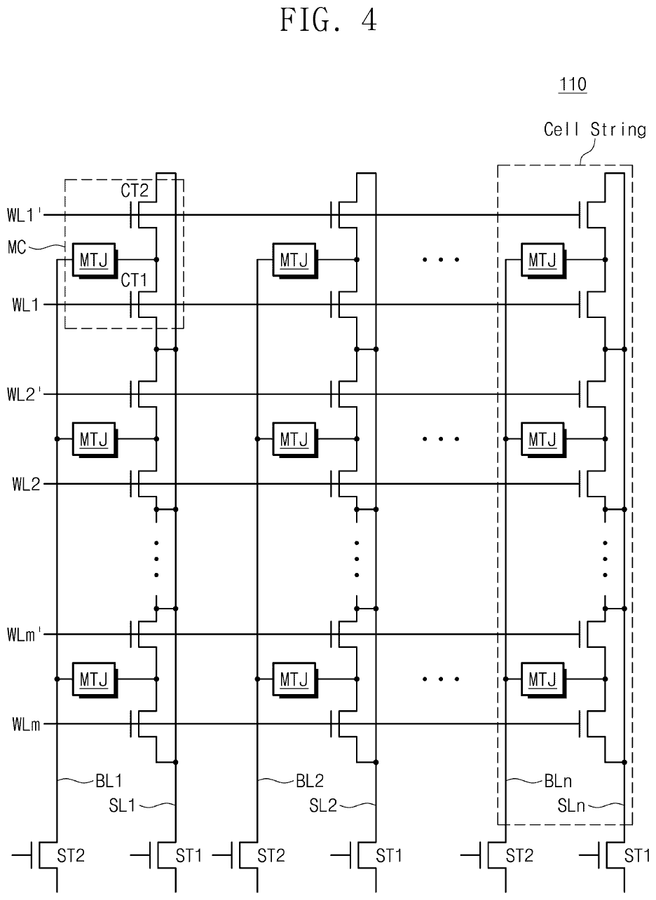

FIG. 4 is a circuit diagram illustrating a configuration of the memory cell array 110 of FIG. 2.

The select transistors ST1 and ST2 among components illustrated in FIG. 4 may constitute the column decoder 130 (refer to FIG. 2) and are illustrated together with the memory cell array 110 to represent the connection relationship with the memory cell array 110.

The memory cell array 110 may include a plurality of memory cells arranged along row and column directions. A memory cell MC may include a magnetic tunnel junction (MTJ) element and two cell transistors CT1 and CT2. A cell string may include a plurality of memory cells which are connected in common to one bit line and one source line.

The memory cell MC may have a structure in which two cell transistors CT1 and CT2 share one MTJ element. A first end of the MTJ element may be connected to the first bit line BL1, and a second end of the MTJ element may be connected to first ends of the cell transistors CT1 and CT2. Second ends of the cell transistors CT1 and CT2 may be connected to the first source line SL1. A gate electrode of the first cell transistor CT1 may be connected to the first word line WL1, and a gate electrode of the second cell transistor CT2 may be connected to a first sub-word line WL1′. Each of the cell transistors CT1 and CT2 may be turned on or turned off by a signal (or a voltage) provided through a word line or a sub-word line.

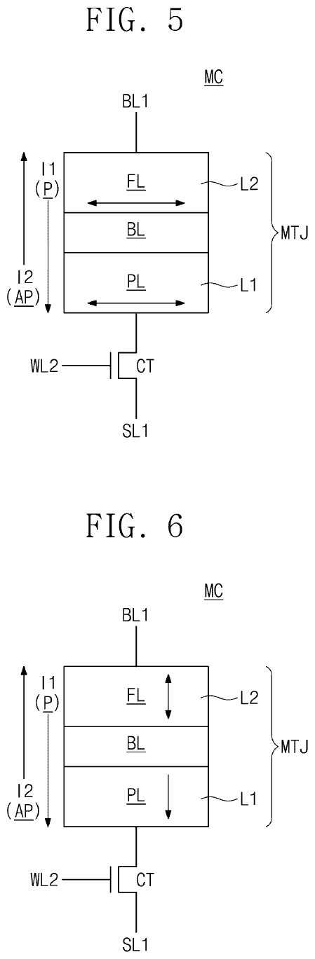

FIGS. 5 and 6 illustrate a configuration of a memory cell, e.g., of FIG. 3.

Referring to FIGS. 5 and 6, an MTJ element may include a first magnetic layer L1, a second magnetic layer L2, and a barrier layer BL (or a tunneling layer) interposed therebetween. The barrier layer BL may include at least one of a magnesium (Mg) oxide layer, a titanium (terminal) oxide layer, an aluminum (Al) oxide layer, a magnesium-zinc (Mg—Zn) oxide layer, or a magnesium-boron (Mg—B) oxide layer, or a combination thereof. Each of the first magnetic layer L1 and the second magnetic layer L2 may include at least one magnetic layer.

The first magnetic layer L1 may include a reference layer (e.g., a pinned layer PL) having a magnetization direction fixed (or pinned) in a specific direction, and the second magnetic layer L2 may include a free layer FL having a magnetization direction changeable to be parallel or anti-parallel to the magnetization direction of the reference layer. FIGS. 5 and 6 show, by way of example, the case where the first magnetic layer L1 includes the reference layer PL and the second magnetic layer L2 includes the free layer FL, but the present disclosure is not limited thereto. For example, unlike the example illustrated in FIGS. 5 and 6, the first magnetic layer L1 may include a free layer, and the second magnetic layer L2 may include a pinned layer.

In some implementations, as illustrated in FIG. 5, magnetization directions may be mostly parallel to an interface of the barrier layer BL and the first magnetic layer L1. In this case, each of the reference layer and the free layer may include a ferromagnetic material. For example, the reference layer may further include an anti-ferromagnetic material for pinning a magnetization direction of the ferromagnetic material.

In some implementations, as illustrated in FIG. 6, magnetization directions may be mostly perpendicular to the interface of the barrier layer BL and the first magnetic layer L1. In this case, each of the reference layer and the free layer may include at least one of a perpendicular magnetic material (e.g., CoFeTb, CoFeGd, or CoFeDy), a perpendicular magnetic material with an L10 structure, a CoPt-based material with a hexagonal-close-packed-lattice structure, and perpendicular magnetic structures, or a combination thereof. The perpendicular magnetic material with the L10 structure may include at least one of FePt with the L10 structure, FePd with the L10 structure, CoPd with the L10 structure, or CoPt with the L10 structure, or a combination thereof. The perpendicular magnetic structure may include magnetic layers and non-magnetic layers which are alternately and repeatedly stacked. For example, the perpendicular magnetic structure may include at least one of Co/Pt)n, (CoFe/Pt)n, (CoFe/Pd)n, (Co/Pd)n, (Co/Ni) n, (CoNi/Pt)n, (CoCr/Pt)n, or (CoCr/Pd)n (n being the number of stacked layers), or a combination thereof. Here, the thickness of the reference layer may be greater than the thickness of the free layer, or a coercive force of the reference layer may be greater than a coercive force of the free layer.

In some implementations, when a voltage of a relatively high level is applied to the bit line BL1 and a voltage of a relatively low level is applied to the source line SL1, a write current I1 may flow. In this case, the magnetization direction of the second magnetic layer L2 may be the same as the magnetization direction of the first magnetic layer L1, and thus, the MTJ element may have a low resistance value (i.e., a parallel state).

In contrast, when a voltage of a relatively high level is applied to the source line SL1 and a voltage of a relatively low level is applied to the bit line BL1, a write current I2 may flow. In this case, the magnetization direction of the second magnetic layer L2 may be opposite to the magnetization direction of the first magnetic layer L1, and thus, the MTJ element may have a large resistance value (i.e., an anti-parallel state).

In some implementations, when the MTJ element is in the parallel state, the memory cell MC may be regarded as storing data of a first value (e.g., logic “0”). In contrast, when the MTJ element is in the anti-parallel state, the memory cell MC may be regarded as storing data of a second value (e.g., logic “1”).

One cell transistor CT is only illustrated in FIGS. 5 and 6, but the components illustrated in FIGS. 5 and 6 may also be applied to the memory cell of FIG. 4. In this case, the cell transistors CT1 and CT2 may be connected to the first end of the MTJ element. The basic principle, operation, etc. of the MTJ element may be identically applied to the memory cell of FIG. 4 except that a current path changes depending on a cell transistor turned on from among the cell transistors CT1 and CT2.

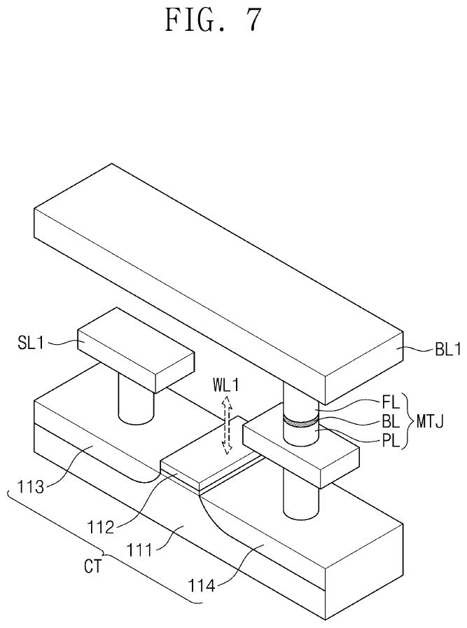

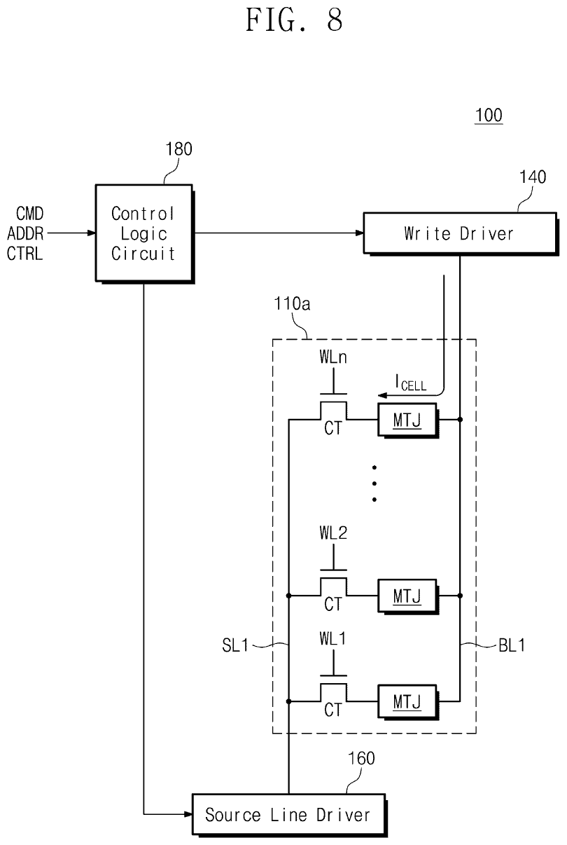

FIG. 7 is a diagram illustrating a configuration associated with a memory cell of FIG. 3.

The cell transistor CT may include a body substrate 111, a gate electrode 112, and junctions 113 and 114. The junction 113 may be formed on the body substrate 111 and may be connected to the source line SL1. The junction 114 may be formed on the body substrate 111 and may be connected to the bit line BL1 through the MTJ element. The gate electrode 112 may be formed on the body substrate 111 between the junctions 113 and 114 and may be connected to the word line WL1.The configuration of FIG. 7 is provided as an example. Like the example described with reference to FIG. 6, in the case where two cell transistors share one MTJ element, a modified version of the configuration illustrated in FIG. 7 may be adopted.

FIG. 8 illustrates components associated with a pre-program or program operation from among components of a memory device of FIG. 2.

In some implementations, a pre-program operation is distinct or different from operations performed for storing data For example, the pre-program operation may be associated with a program operation for searching for an optimal value of the reference resistance for distinguishing the parallel state and the anti-parallel state in the process of testing a memory device. A pre-program voltage may be a voltage whose level is sufficient to result in the program operation on memory cells not failing. Accordingly, the level of the pre-program voltage may be higher than the level of the program voltage used in a normal program operation. This may be associated with preventing a program fail state in order to accurately perform the test operation.

The memory cell array 110 (refer to FIG. 2) may include a plurality of memory cells each including an MTJ element and a cell transistor. The write driver 140, the source line driver 160, and the control logic circuit 180 are illustrated together with a first region 110a of the memory cell array 110. The memory cells may be connected to the write driver 140 through the first bit line BL1 and may be connected to the source line driver 160 through the first source line SL1.

The control logic circuit 180 may be configured to generate a voltage for performing the pre-program operation on the first region 110a of the memory cell array 110. For example, the control logic circuit 180 may individually control components constituting the write driver 140, based on the control signal CTRL.

The write driver 140 may perform the pre-program operation on memory cells under control of the control logic circuit 180. The pre-program operation may include programming the memory cells to have the parallel state and/or programming the memory cells to have the anti-parallel state. The write driver 140 may output a write current I_{CELL} (or a write voltage) corresponding to the parallel state or the anti-parallel state. For example, the write driver 140 may include a driver circuit configured to generate the write current I_{CELL} to perform the pre-program operation on the memory cells.

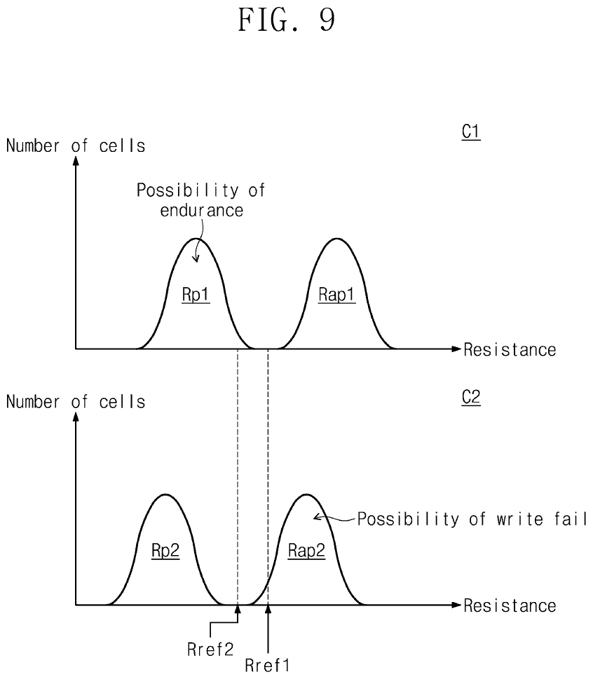

FIG. 9 illustrates resistance distributions of pre-programmed (or programmed) memory cells.

Like the description briefly given with reference to FIG. 1, the program characteristics of the memory chips C1 and C2 manufactured from the same substrate 1 may be different from each other due to various process issues. For example, a resistance distribution diagram corresponding to the first memory chip C1 may be different from a resistance distribution diagram corresponding to the second memory chip C2. When the size of the MRAM cell belonging to the first memory chip Cl is smaller than the size of the MRAM cell belonging to the second memory chip C2, resistance values of the MRAM cells of the first memory chip C1 may be mostly more than resistance values of the MRAM cells of the second memory chip C2.

In addition, a value of a program voltage (or switching current) necessary to perform the program operation on the MRAM cell of the first memory chip C1 may be mostly less than a value of a program voltage (or switching current) necessary to perform the program operation on the MRAM cell of the second memory chip C2. However, in another some implementations, when the size of the MRAM cell belonging to the first memory chip C1 is larger than the size of the MRAM cell belonging to the second memory chip C2, the resistance characteristics and the program voltage characteristics may be opposite to those described above.

In some implementations, the memory cells of the first memory chip C1 have a resistance distribution Rp1 and a resistance distribution Rap1. The resistance distribution Rp1 indicates a resistance distribution of memory cells programmed to the parallel state, and the resistance distribution Rap1 indicates a resistance distribution of memory cells programmed to the anti-parallel state. The resistance distributions Rp1 and Rap1 may be distinguished by a first reference resistance Rref1. The memory cells of the second memory chip C2 may have a resistance distribution Rp2 and a resistance distribution Rap2. The resistance distribution Rp2 indicates a resistance distribution of memory cells programmed to the parallel state, and the resistance distribution Rap2 indicates a resistance distribution of memory cells programmed to the anti-parallel state. The resistance distributions Rp2 and Rap2 may be distinguished by a second reference resistance Rref2.

However, a magnitude of the program voltage corresponding to the first reference resistance Rref1 may be too small to properly program the memory cells of the second memory chip C2. The reason is that a relatively large program voltage (or switching current) may be optimal to program the memory cells of the second memory chip C2 in which a cell size is relatively large. For example, a write fail event may occur when the program operation on the memory cells of the second memory chip C2 is performed by using the relatively small program voltage corresponding to the first reference resistance Rref1. For example, in the write fail event, the program voltage may be insufficient to flip the magnetization of the memory cell.

Further, a magnitude of the program voltage corresponding to the second reference resistance Rref2 may be too large to properly program the memory cells of the first memory chip C1. The reason is that a relatively small program voltage (or switching current) may be optimal to program the memory cells of the first memory chip C1 in which a cell size is relatively small. For example, when the program operation of the first memory chip C1 is performed by using the relatively large program voltage corresponding to the second reference resistance Rref2, an endurance issue may occur at memory cells.

As a result, unintended results may occur when the write operation on the memory chips C1 and C2 manufactured from one wafer (e.g., 1 of FIG. 1) is performed by using the same reference resistance value. Accordingly, according to some implementations of the present disclosure, an initial program voltage value is determined by using a reference resistance value to be applied to determine program states of memory cells of a memory device (coarse trim). In addition, the value of the program voltage is determined finely around the initial program voltage value to apply a variation in the program voltage (or switching current) (fine trim), e.g., to account for process variation.

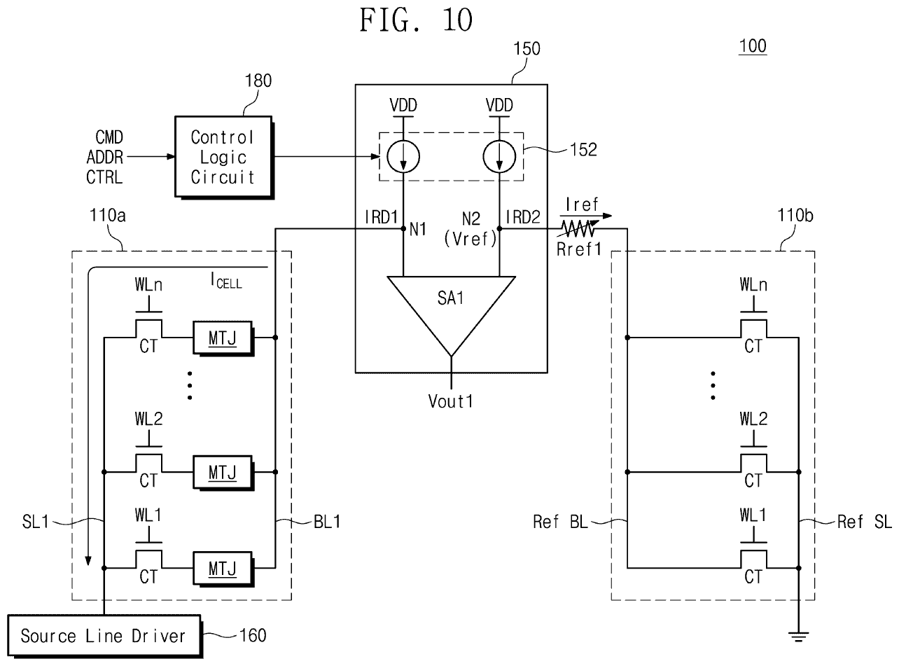

FIG. 10 illustrates a circuit configuration associated with a read operation on the memory cell array 110 of FIG. 2.

In some implementations, the read operation is an operation of reading fail bits to determine an optimal value of the reference resistance in the process of testing a memory device. In some implementations, the read operation is an operation of reading data stored in memory cells at an end-user level. For example, to read a fail bit and to determine an optimal value of the reference resistance, a value of the reference resistance Rref1 may vary under control of the control logic circuit 180.

The memory device 100 may include a memory cell array composed of the first region 110a and a second region 110b, the sensing circuit 150, the source line driver 160, and the control logic circuit 180. For brevity of illustration, one of the cell strings of the first region 110a is illustrated.

The first region 110a may include a plurality of memory cells connected to the first bit line BL1 and the first source line SL1, and each memory cell may include an MTJ element and a cell transistor. The first bit line BL1 may be connected to a first node N1, and the first source line SL1 may be connected to the source line driver 160.

The second region 110b may include components which are necessary to generate a reference voltage Vref which is used to read data stored in a memory cell of the first region 110a. The second region 110b may include a reference bit line Ref BL, a reference source line Ref SL, and a plurality of cell transistors CT. The second region 110b may be called a dummy region in that an MTJ element is not included therein, and a memory cell of the second region 110b may be called a dummy memory cell.

The sensing circuit 150 may be configured to read data stored in a memory cell connected to the first bit line BL1. For example, the sensing circuit 150 may include a current source circuit 152 generating a first read current IRD1 and a second read current IRD2, and a sense amplifier SA1.

The first read current IRD1 may be used to sense a voltage drop on the first bit line BL1, which is caused depending on a state of a selected memory cell. For example, the first read current IRD1 may be input to the MTJ element of the selected memory cell which is connected to a selected word line (i.e., WLm) and the first bit line BL1. As a result, the voltage drop is made by the MTJ element connected to the m-th word line WLm.

The second read current IRD2 may be used to determine a voltage drop made by the first reference resistance Rref1 connected to a second node N2 through the reference bit line Ref BL. For example, when the second read current IRD2 flows through the first reference resistance Rref1, the voltage drop may be made by the first reference resistance Rref1. A reference current Iref is illustrated in FIG. 10 to show a current flowing through the reference resistance Rref1, but in some implementations the reference current Iref may be regarded as substantially/mostly the same as the second read current IRD2.

The sense amplifier SA1 may sense a voltage difference between the first node N1 and the second node N2 and may amplify the sensed voltage difference. Depending on a program state of a memory cell, a voltage level of the first node N1 may be different from a voltage level of the second node N2. The amplified voltage difference may be output as an output voltage Vout1 and may be used to determine the data read from the memory cell.

In some implementations, in the process of testing the memory device 100, the number of fail bits of memory cells programmed to the parallel state or the anti-parallel state is counted for each value of the reference resistance Rref1. A value of a reference resistance for determining program states of the memory cells of the memory device 100 may be obtained based on the number of fail bits. The obtained reference resistance value may be adopted as a value of the first reference resistance Rref1.

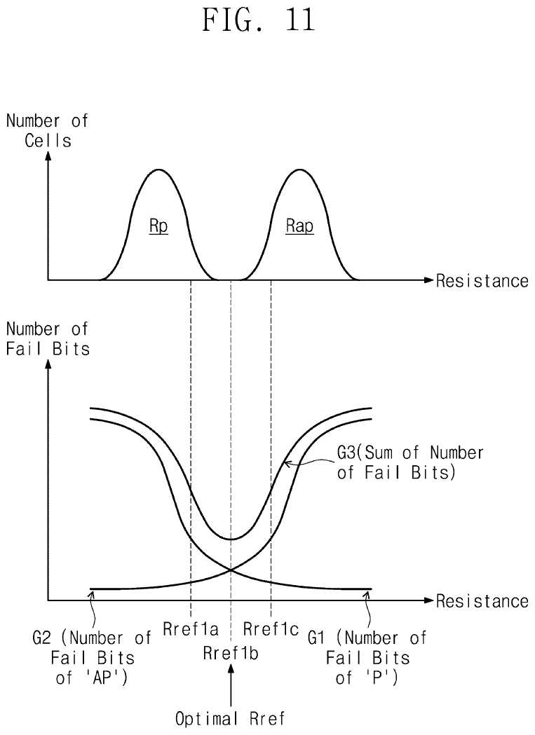

FIG. 11 illustrates an example of how to determine a value of a global reference resistance for distinguishing a program state of a memory cell.

Referring to FIGS. 9, 10, and 11, during the test operation of the memory device 100, the pre-program operation on the memory device 100 may be performed. First, a test device (e.g., automatic test equipment (ATE)) may program the memory cells of the memory device 100 to the parallel state. In FIG. 11, “Rp” indicates a distribution of resistance values of the memory cells programmed to the parallel state.

The test device may count the number of fail bits of the memory cells of the memory device 100. For example, when the read operation is performed by using a reference resistance of a relatively small value (e.g., Rref1a), the number of fail bits may be large. As a value (e.g., Rref1c) of the reference resistance becomes greater, the number of fail bits may decrease. As the reference resistance value varies, the number of counted fail bits varies like a graph marked by G1.

When the fail bit counting for the memory cells programmed to the parallel state is completed, the test device may program the memory cells of the memory device 100 to the anti-parallel state. In FIG. 11, “Rap” indicates a distribution of resistance values of memory cells programmed to the anti-parallel state.

The test device may count the number of fail bits of the memory cells of the memory device 100. For example, when the read operation is performed by using a reference resistance of a relatively small value (e.g., Rref1a), the number of fail bits may be small. As a value (e.g., Rref1c) of the reference resistance becomes greater, the number of fail bits in the memory device may increase. As the reference resistance value varies, the number of counted fail bits varies like a graph marked by G2.

The test device may sum the graph G1 indicating the number of fail bits measured in the parallel state and the graph G2 indicating the number of fail bits measured in the anti-parallel state. A graph indicated by G3 may be drawn as a sum result. In the graph indicated by G3, a resistance value (i.e., Rref1b) corresponding to the smallest number of fail bits may be adopted as an optimal reference resistance value Rref1 of the memory device 100.

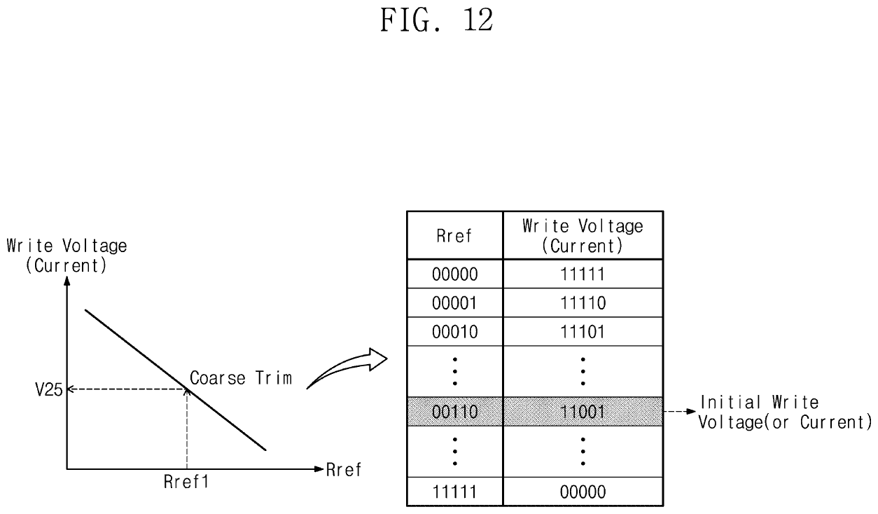

FIG. 12 conceptually illustrates an example of how to determine a value of a write voltage based on a reference resistance value determined in FIG. 11.

In some implementations, a reference resistance value of a memory device may be inversely proportional to a value of a write voltage (or switching current) of the memory device, which corresponds to the reference resistance value. However, the write voltage (or switching current) corresponding to the reference resistance value of the memory device may not be accurately or exactly the an optimal value of the write voltage (or switching current). It should be understood that a value of a write voltage (or switching current) decreases as a value of a reference resistance increases.

In some implementations, each of a reference resistance value and a write voltage (or switching current) value is expressed using 5 bits, but the present disclosure is not limited to the foregoing number of bits. In the case where the reference resistance value is expressed by 5 bits, the fail bit counting operation described with reference to FIG. 11 may be performed as many as 32 (25) times or less for each of the parallel state and the anti-parallel state. For example, the read/write voltage (or current) may be variable between a first value corresponding to “11111” and a second value corresponding to “00000”. For example, the reference resistance may be stepped from Rref1a to Rref1c,
in the process of FIG. 11, such that 32 different reference resistances values are tested.

As an example, a logical value corresponding to the optimal reference resistance value Rref1 of the memory device may be “00110”, and a logical value of the write voltage value corresponding thereto may be “11001”. The above operation of obtaining an initial value of the write voltage depending on the relationship between the write voltage and the reference resistance (e.g., as described with respect to FIGS. 11-12) may be called coarse trim.

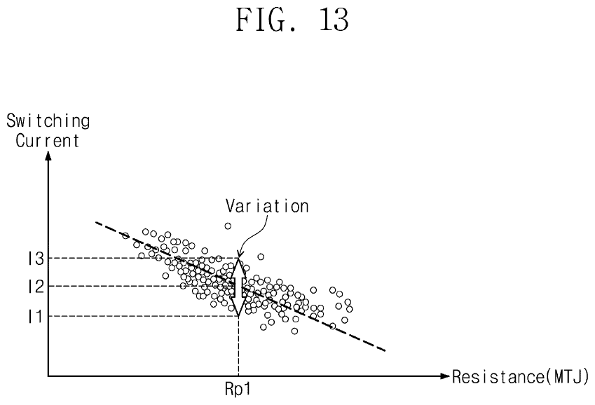

FIG. 13 is a graph illustrating a correlation relationship between an MTJ resistance and a switching current of an MRAM cell.

In FIG. 13, the horizontal axis represents an MTJ resistance of a memory cell programmed to the parallel state, and the vertical axis represents a switching current for programming a memory cell. Plotting points indicate a distribution of memory cells. The thick dotted line indicates an average of a distribution of the plotted memory cells.

As described above, a value of a reference resistance for determining a program state of an MRAM cell correlates with a value of an MTJ resistance, and an initial write voltage value, is determined based on the reference resistance value (coarse trim). Accordingly, write voltage (or switching current) values for memory cells having the same MTJ resistance value should be, in principle, identical to each other.

However, even when MRAM cells have the same MTJ resistance value, there may be a variation in a value of the program voltage (or switching current) as illustrated in FIG. 13. For example, switching current values for a plurality of MRAM cells with the same MTJ resistance value (e.g., is, with an MTJ resistance of Rp1) may be various and may be distributed between I1 and I3. Herein, the switching current value 12 may correspond to the optimal initial write voltage V25 determined in the coarse trim process of FIGS. 11-12. “V25” here indicates that, in the coarse trim process, the optimal initial write voltage corresponds to the 26th out of 32 tested reference resistance values (with counting start at V0).

Using the switching current value of 12 for an MRAM cell in which a value of an MTJ resistance is Rp1 and a value of a switching current is I1 may result in the program operation being performed using an excessive current; in this case, the endurance issue of the MRAM cell may be caused. Using the switching current value of I2 for an MRAM cell in which a value of an MTJ resistance is Rp1 and a value of a switching current is I3 may result in the program operation being performed using an insufficient current; in this case, the program fail issue may be caused.

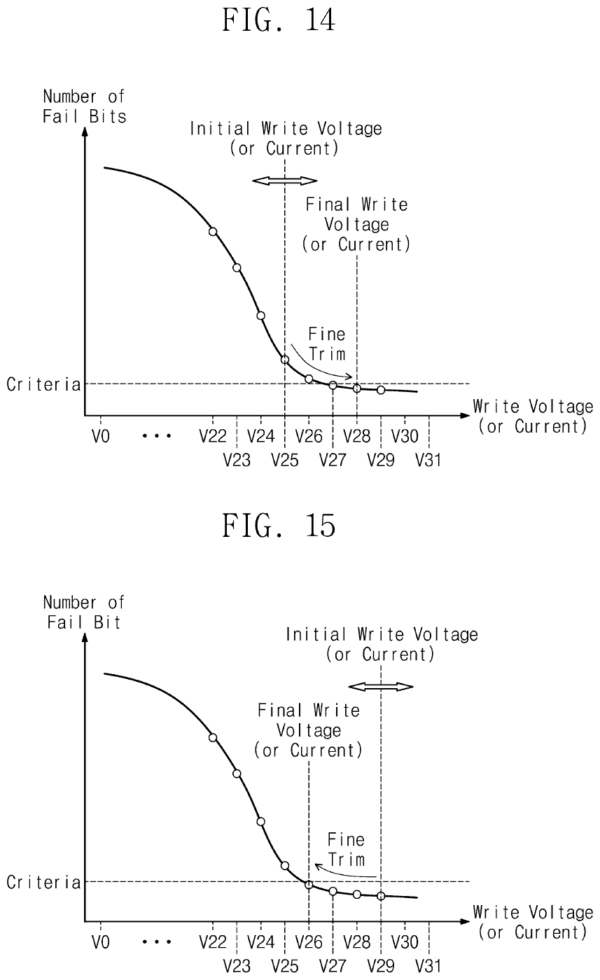

FIG. 14 is a graph illustrating an example of how to obtain an optimal write voltage value through fine trim, in order to remedy the foregoing effects.

The test device may perform the fine trim from an initial write voltage value V25 as a start point, e.g., an initial write voltage value corresponding to the reference resistance determined in the coarse trim process. For example, the test device may program memory cells of a memory device by using the write voltage whose value is V25. The test device may count fail bits of the programmed memory cells, e.g., by reading the programmed memory cells. The test device may compare the number of fail bits with a criteria. Herein, the criteria may be a threshold value such as a number of fail bits which is determined to be allowable by a memory vendor in terms of the reliability of the memory device. When the number of fail bits is more than the criteria, the test device may determine that the initial write voltage value V25 is not an optimal write voltage value.

The test device may program the memory cells of the memory device by using a next write voltage value V26. The test device may count fail bits of the programmed memory cells. The test device may compare the number of fail bits with the criteria. Because the number of fail bits is still more than the criteria, the test device may determine that the initial write voltage value V26 is not the optimal write voltage value.

The test device may program the memory cells of the memory device by using a next write voltage value V27. The test device may count fail bits of the programmed memory cells. The test device may compare the number of fail bits with the criteria. Because the number of fail bits is less than the criteria, the test device may determine the write voltage value V27 as the optimal write voltage value.

FIG. 15 is a graph illustrating an example of how to obtain an optimal write voltage value through fine trim.

The test device may perform the fine trim from an initial write voltage value V29 as a start point. For example, the test device may program memory cells of a memory device by using the write voltage whose value is V29. The test device may count fail bits of the programmed memory cells. The test device may compare the number of fail bits with the criteria. Because the number of fail bits is less than the criteria, the write voltage value V29 may be an appropriate write voltage value. However, the probability that the number of fail bits is less than the criteria when the write voltage of a smaller value is used may exist; in this case, the write voltage whose value is V29 may be a voltage whose magnitude is excessive to program the memory device. Accordingly, the test device may postpone the determination about whether the write voltage whose value is V29 is an appropriate write voltage value.

The test device may program the memory cells of the memory device by using a next write voltage value V28. The test device may count fail bits of the programmed memory cells, e.g., by reading the programmed memory cells. The test device may compare the number of fail bits with the criteria. Because the number of fail bits is still less than the criteria, the test device may repeat an operation of comparing the number of fail bits with the criteria as the program operation is respectively performed by using next write voltage values V27 and V26. Because the number of fail bits associated with the write voltage value V26 is still less than the criteria, the probability that the write voltage value V26 is still not the optimal write voltage value exists.

The test device may program the memory cells of the memory device by using the write voltage value V25. The test device may count fail bits of the programmed memory cells. The test device may compare the number of fail bits with the criteria. Because the number of fail bits is more than the criteria, the test device may determine that the write voltage value V25 is not the optimal write voltage value. As a result, the test device may determine the previous write voltage value V26 as the optimal write voltage value.

In some implementations, an optimal write voltage value is obtained in a binary search method in which a write voltage value sequentially increases or decreases as described above. In some implementations, an optimal write voltage value may be obtained in a linear search method. However, the method of obtaining an optimal write voltage value is not limited thereto, and various methods (e.g., search and optimization methods) may be used.

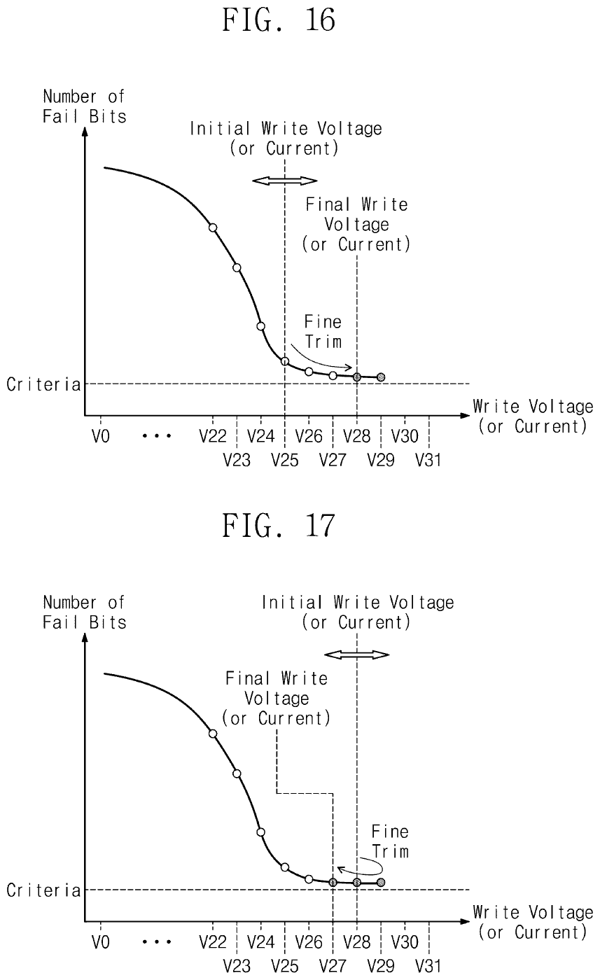

The fine trim methods described with reference to FIGS. 14 and 15 may be changed or modified within the scope of this disclosure. For example, when a hard fail such as an open circuit fail or a short-circuited fail exists at many memory cells of the memory device, the number of fail bits due to the hard fail may somewhat increase compared to a normal case. Fine trim processes associated with this case will be described with reference to FIGS. 16 to 18.

FIG. 16 is a graph illustrating another example of how to obtain an optimal write voltage value through fine trim.

The test device may perform the fine trim from the initial write voltage value V25 as a start point. As the test device performs fail bit counting while increasing a write voltage value from V25 to V28, the number of fail bits may gradually decrease.

However, when many hard fails exist, a minimum value among fail bit counting values of the memory device may exceed the criteria. In some implementations, the number of fail bits of the memory device performing the program operation by using the write voltage whose value is V28 may be equal to the number of fail bits of the memory device performing the program operation by using the write voltage whose value is V29. In this case, even though the write voltage value is continuously increased, the number of fail bits may not decrease any more due to the hard fails. Accordingly, even though the number of fail bits is more than the criteria, the test device may determine the previous write voltage value V28 among the write voltage values V28 and V29, at which the same number of fail bits occurs, as an optimal write voltage value.

In this example, a previous write voltage value (e.g., V28 compared to V29) is selected as an optimal write voltage value when a fail bit counting value does not change, but this aspect may be variously changed or modified. For example, in some implementations, the fine time is terminated based on a change in a fail bit counting value not exceeding a threshold value. For example, it is assumed that the number of fail bits of the memory device performing the program operation by using the write voltage whose value is V28 is “n” and the number of fail bits of the memory device performing the program operation by using the write voltage whose value is V29 “n−Δ”. Under the assumption, when “Δ” is a value within the threshold value, the write voltage value V28 may be determined as an optimal write voltage value.

FIG. 17 is a graph illustrating another example of how to obtain an optimal write voltage value through fine trim.

The test device may perform the fine trim from the initial write voltage value V28 as a start point. As the test device performs fail bit counting while increasing a write voltage value from V28 to V29, the number of fail bits may be uniform. In the example described with reference to FIG. 16, the write voltage value V28 is selected as an optimal write voltage value.

In some implementations, as in the example of FIG. 17, the test device may program the memory cells of the memory device by using a previous write voltage value V27 and may count the number of fail bits. When the number of fail bits associated with the write voltage value V27 is determined to be equal to the number of fail bits associated with the write voltage value V28 and the number of fail bits associated with the write voltage value V26 is determined to be more than the number of fail bits associated with the write voltage value V27, the write voltage value V27 may be determined as an optimal write voltage value. “Equal to” in the foregoing description can be equally replaced by “having a difference A within a threshold value” as discussed with respect to FIG. 16.

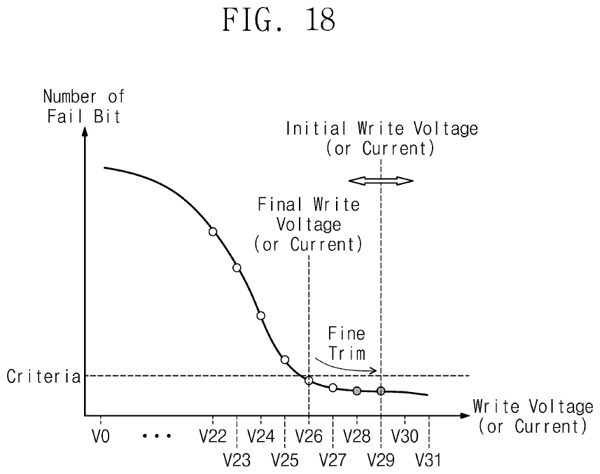

FIG. 18 is a graph illustrating another example of how to obtain an optimal write voltage value through fine trim.

The test device may perform the fine trim from the initial write voltage value V29 as a start point. In this example, because the number of fail bits of memory cells programmed by using the initial write voltage value V29 is less than the criteria, the fine trim may be performed while decreasing a write voltage value (i.e., in a left direction in the plot of FIG. 18).

As the test device performs fail bit counting while decreasing a write voltage value from V29 to V28, the number of fail bits associated with the write voltage value V29 may be equal to (or have a difference within a predetermined threshold of) the number of fail bits associated with the write voltage value V28. In the examples described with reference to FIG. 16 or 17, the write voltage value V28 may be selected as an optimal write voltage value. However, in this case, because it is possible for the number of fail bits to increase when fail bit counting is performed while decreasing a write voltage value, the write voltage value V28 may not be selected as an optimal write voltage value.

The test device may sequentially perform fail bit counting operations respectively associated with next write voltage values V27, V26, and V25. According to the scheme described with reference to FIG. 15, the write voltage value V26 corresponding to the number of fail bits, which is just below the criteria (e.g., for which a next-lowest write voltage value is above the criteria), may be selected as an optimal write voltage value.

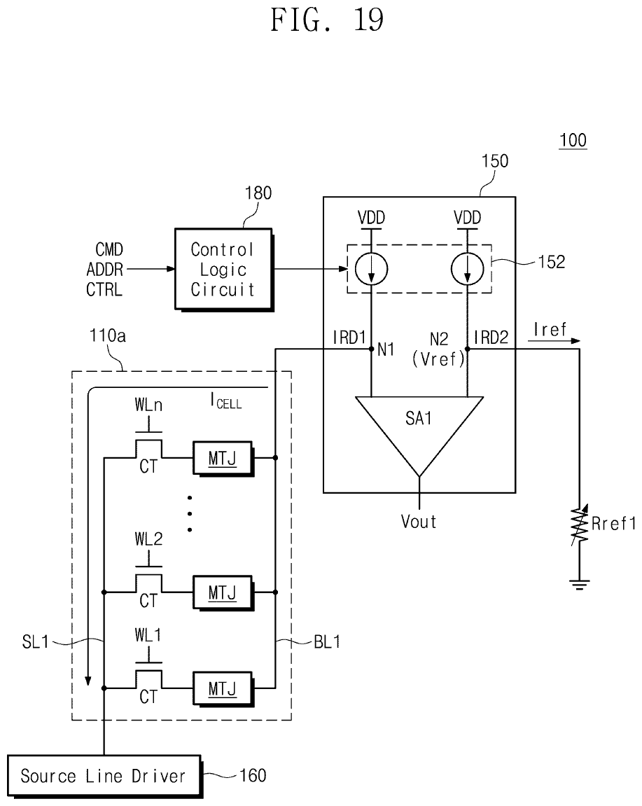

FIG. 19 illustrates a circuit configuration associated with a read operation on the memory cell array 110 of FIG. 2.

The memory device 100 may include a memory cell array composed of the first region 110a, the sensing circuit 150, the source line driver 160, and the control logic circuit 180. In this example, the memory cell array does not include a dummy region, and the reference resistance Rref1 is connected between the second node N2 and a ground electrode. A configuration and an operation of the memory cell array 110 of FIG. 19 are mostly the same as those of the memory cell array of FIG. 10 except for the above difference, and thus, additional description will be omitted to avoid redundancy; characteristics and operations of the memory cell array of FIG. 19 are the same as disclosed for FIG. 10 except where noted otherwise or suggested otherwise by context.

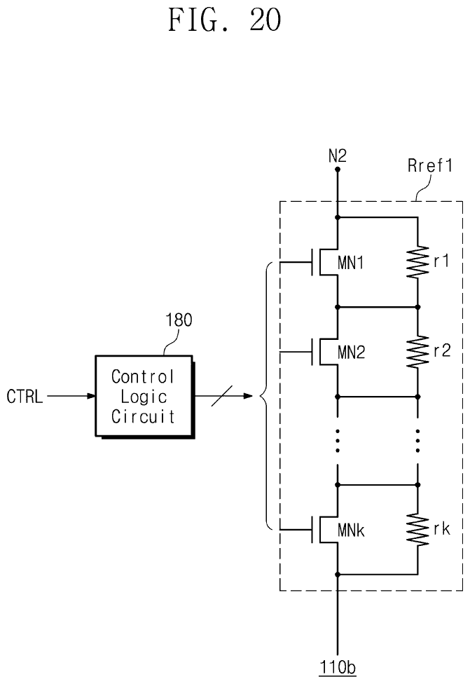

FIG. 20 illustrates an example of a circuit configuration of the reference resistance Rref1 of FIG. 10 or 19.

The reference resistance Rref1 may be configured such that a resistance value thereof is changed under control of the control logic circuit 180. For example, the control logic circuit 180 may control the reference resistance Rref1, based on the control signal CTRL including information about the optimal reference resistance value determined according to FIG. 11. For example, the information about the optimal local reference resistance value may be read from the OTP memory of the memory device 100.

In some implementations, the reference resistance Rref1 includes a plurality of transistors MN1 to MNk and a plurality of resistance elements r1 to rk. The plurality of transistors MN1 to MNk may be individually turned on or turned off under control of the control logic circuit 180. When a transistor is turned on, a current may flow from the second node N2 to the ground electrode; in this case, it may be regarded as no current flowing through a resistance element connected between opposite ends of the turned-on transistor. For example, when the transistor MN1 is turned off and the remaining transistors MN2 to MNk are turned on, a path of a current flowing from the second node N2 to the ground electrode may be “r1−MN2−, . . . , −MNk”, and a value of the reference resistance Rref1 may be “r1”.

However, the configuration of the reference resistance Rref1 is not limited to the example illustrated in FIG. 20, and various configurations in which a resistance value is changed under control of the control logic circuit 180 may be adopted.

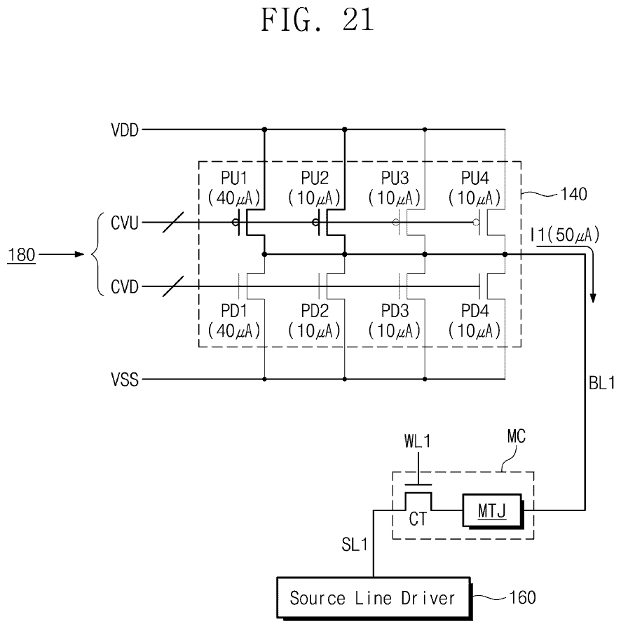

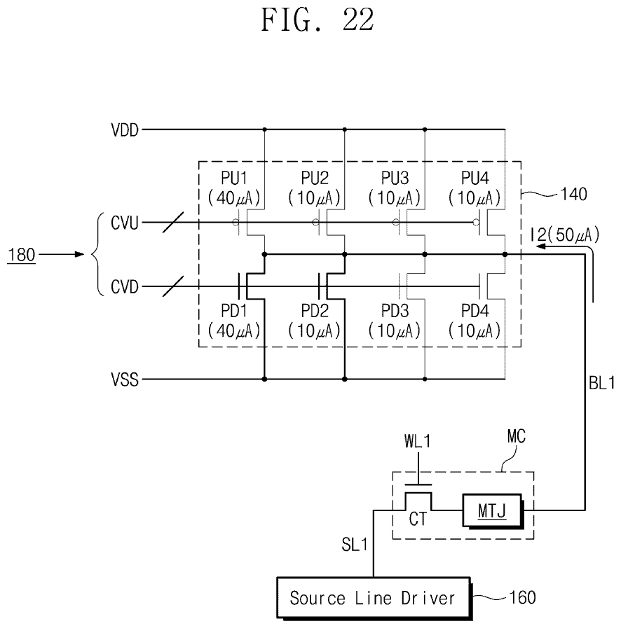

FIGS. 21 and 22 are circuit diagrams illustrating a pre-program operation or a program operation of the write driver 140 of FIG. 8.

Referring to FIGS. 21 and 22, the write driver 140 may include transistors PU1 to PU4 and transistors PD1 to PD4. For example, each of the transistors PU1 and PD1 may have a channel width for driving a current of 40 μA, and each of the transistors PU2 to PU4 and PD2 to PD4 may have a channel width for driving a current of 10 μA.

In some implementations, FIG. 21 is associated with the case where the write driver 140 pulls up a voltage of the first bit line BL1 to a first power supply voltage VDD. In the example of FIG. 21, the write driver 140 may receive a first code value CVU of “0011” and a second code value CVD of “0000” from the control logic circuit 180 (refer to FIG. 8).

Referring to FIG. 21, the transistors PD1 to PD4 may be turned off in response to the second code value CVD. The transistors PU1 and PU2 may be turned on in response to bits of “00” of the first code value CVU, and the transistors PU3 and PU4 may be turned off in response to bits “11” of the first code value CVU. Accordingly, a write current I1 of 50 μA may be driven through the turned-on transistors PU1 and PU2.

In some implementations, FIG. 22 is associated with the case where the write driver 140 pulls down a voltage of the first bit line BL1 to a second power supply voltage VSS. In the example of FIG. 22, the write driver 140 may be provided with the first code value CVU of “1111” and the second code value CVD of “1100” from the control logic circuit 180.

Referring to FIG. 22, the transistors PU1 to PU4 may be turned off in response to the first code value CVU. The transistors PD1 and PD2 may be turned on in response to bits of “11” of the second code value CVD, and the transistors PD3 and PD4 may be turned off in response to bits “00” of the second code value CVD. Accordingly, a write current I2 of 50 μA may be driven through the turned-on transistors PD1 and PD2.

In some implementations, the example of FIG. 21 is associated with the case of storing data of logic “0” in the memory cell MC, and the example of FIG. 22 is associated with the case of storing data of logic “1” in the memory cell MC. For example, to provide the code values CVU and CVD to the transistors PU1 to PU4 and PD1 to PD4 constituting the write driver 140, the control logic circuit 180 may include components such as a switch and a multiplexer.

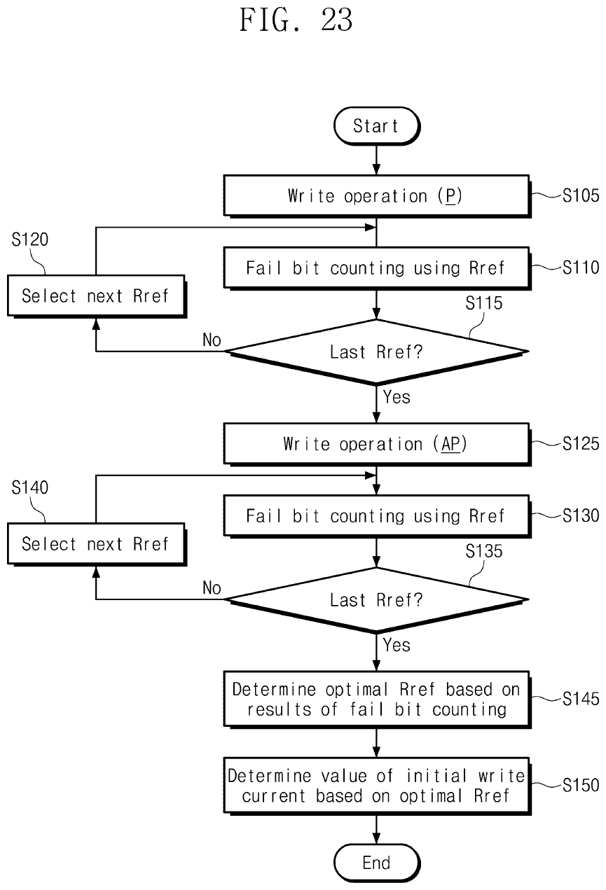

FIG. 23 is a flowchart illustrating a test method of a memory device according to some implementations of of the present disclosure. The test method may be performed, for example, by a test device.

In operation S105, the pre-program operation on the memory cells of the memory device is performed. For example, the test device may program the memory cells constituting the memory device to the parallel state (e.g., Rp of FIG. 11).

In operation S110, fail bit counting for the memory cells of the memory device is performed. In some implementations, the test device counts the number of fail bits of the memory cells while varying a value of the reference resistance Rref1. The reference resistance value may be varied as the control logic circuit 180 controls the reference resistance Rref1, as illustrated in FIG. 20, under control of the test device. The test device may count fail bits of the memory cells while varying a value of the reference resistance Rref1 (e.g., may repeatedly perform operation S110, operation S115, and operation S120). When the fail bit counting using all the reference resistance values is completed, the fail bit counting operation associated with the parallel state may end.

In operation S125, the pre-program operation on the memory cells of the memory device is performed. For example, the test device may program the memory cells constituting the memory device to the anti-parallel state (e.g., Rap of FIG. 11).

In operation S130, fail bit counting for the memory cells of the memory device is performed. In some implementations, the test device counts the number of fail bits of the memory cells while varying a value of the reference resistance Rref1.

Afterwards, the test device may count the number of fail bits of the memory cells while varying a value of the reference resistance Rref1 (e.g., may repeatedly perform operation S130, operation S135, and operation S140); when the fail bit counting using all the reference resistance values is completed, the fail bit counting operation on the anti-parallel state may end.

In operation S145, an optimal reference resistance value is determined based on fail bit counting results. For example, the test device may sum the number of fail bits in the parallel state counted for each reference resistance value and the number of fail bits in the anti-parallel state counted for each reference resistance value and may select a resistance value having the smallest summation result as the reference resistance value.

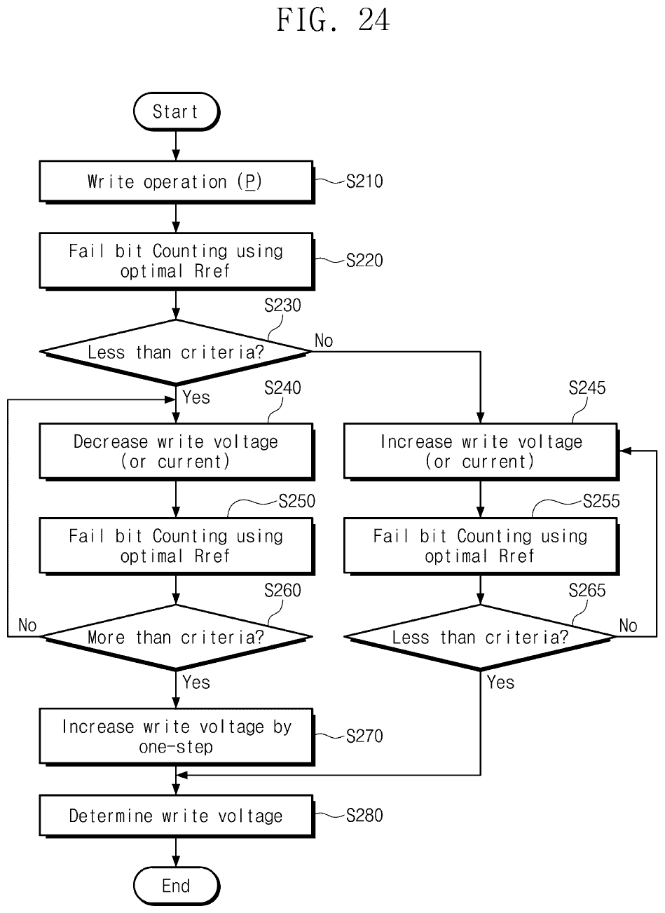

FIG. 24 is a flowchart illustrating a test method of a memory device according to some implementations of the present disclosure. The test method may be performed, for example, by a test device.

In operation S210, the program operation on the memory device may be performed. For example, the test device may program the memory cells of the memory device to the parallel state.

In operation S220, fail bit counting using an optimal reference resistance value may be performed. For example, the test device may perform the read operation on the memory cells programmed to the parallel state by using the optimal reference resistance value determined in FIG. 23 and may count fail bits, e.g., by using a write voltage corresponding to the optimal reference resistance value.

In operation S230, whether a result of the fail bit counting performed in operation S220 is less than the criteria is determined. When the result of the fail bit counting is less than the criteria (Yes), the test device may decrease a value of the write voltage (S240). The test device may perform the read operation on the memory cells by using the write voltage of the decreased value and may count fail bits (S250). The case where the fail bit counting value is less than the criteria may correspond to the example of FIG. 15.

In operation S260, whether a result of the fail bit counting performed in operation S250 is more than the criteria is determined. When the fail bit counting result is more than the criteria (Yes), the test device may increase the value of the write voltage by one step (S270), and the increased write voltage value may be selected as a final write voltage value. Comparing the example of FIG. 24 with the example of FIG. 15, the case where the result of the fail bit counting performed in operation S250 is more than the criteria may correspond to the case where the write voltage value is V25. Accordingly, an immediately previous write voltage value V26 may be selected as an optimal write voltage value less than the criteria. When the fail bit counting result is less than the criteria (No), operation S240 may be performed.

Meanwhile, when the result of the fail bit counting performed in operation S230 is more than the criteria (No), the test device increases the value of the write voltage (S245). The test device may perform the read operation on the memory cells by using the write voltage of the increased value and may count fail bits (S255). The case where the fail bit counting value is more than the criteria may correspond to the example of FIG. 14.

In operation S265, whether a result of the fail bit counting performed in operation S255 is less than the criteria is determined. When the fail bit counting result is less than the criteria (Yes), the test device may select, as a final write voltage value, a write voltage value which causes a fail bit counting result less than the criteria (S280). In When the fail bit counting result is more than the criteria (No), operation S245 may be performed.

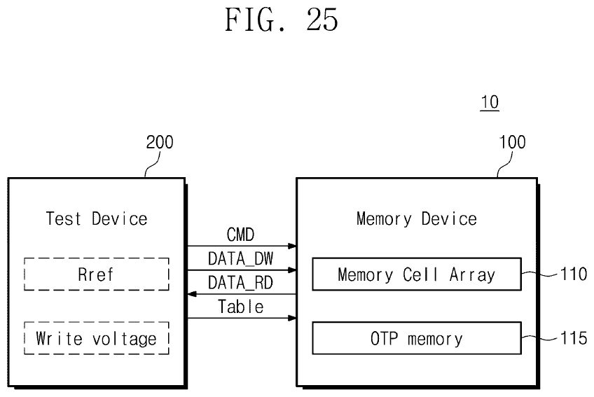

FIG. 25 is a block diagram illustrating a test system for testing a memory device according to some implementations of the present disclosure.

A test system 10 may include the memory device 100 and a test device 200. The memory device 100 may include the memory cell array 110. The memory device 100 may be any of the memory devices 100 described with respect to FIGS. 1 to 24. The memory cell array 110 may include a first region (e.g., 110a of FIG. 10) and a second region (e.g., 110b of FIG. 10). The first region 110a may be a region where data intended by the user are stored, and the second region 110b may be a dummy region.

The memory device 100 may include an OTP memory 115. For example, the OTP memory 115 may store the reference resistance value and write voltage value described with reference to FIGS. 1 to 23. The reference resistance value may be loaded and used in the read operation of the memory device 100, and the write voltage value may be loaded and used in the write operation of the memory device 100.

The test device 200 may perform various test operations on the memory device 100. To this end, the test device 200 may transmit the command CMD to the memory device 100. The test device 200 can include a computing device and suitable interconnections with the memory device 100, e.g., wiring, cabling, pin contacts, etc., for transmitting and receiving data with the memory device 100.

In some implementations, the command CMD includes a command for programming the first region 110a of the memory cell array 110 to a specific program state (e.g., the parallel state or the anti-parallel state). The test device 200 may transmit dummy write data DATA_DW for programming the first region 110a to the parallel state or the anti-parallel state, together with transmitting the command CMD.

In some implementations, the command CMD is used to perform the read operation for counting the number of fail bits for each reference resistance value in association with the specific program state (e.g., the parallel state or the anti-parallel state). Read data DATA_RD may be received from the memory device 100 as a read result.

In some implementations, the test device 200 counts the number of fail bits for each reference resistance value based on the read data DATA_RD received from the memory device 100 and determines an optimal reference resistance value based on counting results.

A memory devices of the present disclosure may provide an optimal write voltage value which is used in the write operation. For example, after obtaining a write voltage value to be globally applied to the memory device through the coarse trim, an optimal write voltage value is obtained by performing the fine trim at a neighboring write voltage close to the write voltage in consideration of a switching current distribution. As a result, the endurance of the memory device may be improved, and a write error of the memory device may be reduced. In addition, as the number of times the write operation is performed in the process of testing the memory device decreases, test costs and a test time may be reduced. For example, the number of write operations can be decreased based on the use of the coarse trim process to determine the initial write voltage to be used in the fine trim.

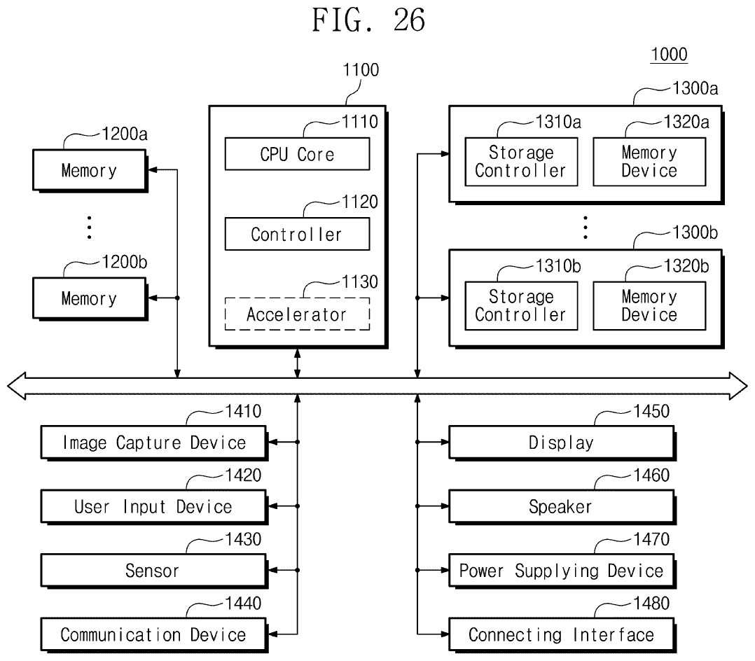

FIG. 26 is a diagram of a system 1000 to which a memory device can be applied, according to some implementations of the present disclosure.

The system 1000 may be a mobile system, such as a portable communication terminal (e.g., a mobile phone), a smartphone, a tablet personal computer (PC), a wearable device, a healthcare device, or an Internet of things (IOT) device. However, the system 1000 is not necessarily limited to the mobile system and may be a PC, a laptop computer, a server, a media player, or an automotive device (e.g., a navigation device), or another such type of device.

The main processor 1100 may control all operations of the system 1000, for example, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some implementations, the main processor 1100 further includes an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVM (Non-Volatile Memory)s 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto. The image capturing device 1410 may capture still images or moving images. The image capturing device 1410 may include a camera, a camcorder, and/or a webcam.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer system interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

The memories and/or memory devices of the system 1000 can include any of the memory devices discussed with respect to FIGS. 1 to 25 and can be operated in accordance with the methods (e.g., test methods) discussed with respect to those figures.

According to some implementations of the present disclosure, a memory device including a magnetic tunnel junction element and implementing an optimal write voltage value capable of solving a write failure and an endurance issue may be provided.

In addition, according to some implementations of the present disclosure, because a time taken to obtain an optimal write voltage is reduced, a test time and test costs may decrease.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure.

What is claimed is:

1. A memory device comprising:
a memory cell array;
a voltage generator configured to generate a code value corresponding to a write voltage; and
a write driver configured to store data in the memory cell array based on the code value,
wherein the memory device is configured to store a value of the write voltage and use the write voltage to program at least one memory cell among a plurality of memory cells of the memory cell array, and is configured to store a value of a reference resistance and use the reference resistance to distinguish between a parallel state and an anti-parallel state of the at least one memory cell, and
wherein the value of the write voltage is based on a value of an initial write voltage corresponding to the value of the reference resistance and a value of a final write voltage obtained based on the value of the initial write voltage.

2. The memory device of claim 1, wherein the at least one memory cell includes:
a cell transistor including a first end connected to a source line and a gate electrode connected to a word line; and
a magnetic tunnel junction element including a first end connected to a second end of the cell transistor and a second end connected to a bit line.

3. The memory device of claim 1, wherein the value of the final write voltage is based on a program operation on the at least one memory cell using at least one voltage value different from the value of the initial write voltage, and based on counting fail bits among the at least one memory cell by a read operation.

4. The memory device of claim 3, wherein the program operation using the at least one voltage value different from the value of the initial write voltage and the read operation are performed in a linear search method or a binary search method.

5. The memory device of claim 1, wherein the write driver includes:
a first type of transistor including a first end connected to a first power supply voltage and a second end connected to an output node; and
a second type of transistor including a first end connected to a second power supply voltage and a second end connected to the output node, and
wherein the output node is connected to the at least one memory cell.

6. The memory device of claim 1, further comprising a sensing circuit configured to determine data stored in the at least one memory cell based on the reference resistance, wherein the sensing circuit includes:
a first current source configured to generate a first read current;
a second current source configured to generate a second read current; and
a sense amplifier configured to amplify a difference between a first voltage drop associated with the first read current and a voltage drop associated with the second read current.

7. The memory device of claim 1, wherein the value of the reference resistance is obtained based on:
a first counting result obtained by performing a fail bit counting operation on the plurality of memory cells programmed to the parallel state using a plurality of resistance values with different values; and
a second counting result obtained by performing the fail bit counting operation on the plurality of memory cells programmed to the anti-parallel state using the plurality of resistance values.

8. The memory device of claim 7, wherein the reference resistance comprises a resistance of a circuit comprising:
a plurality of transistors; and
a plurality of resistance elements respectively corresponding to the plurality of transistors, each of the plurality of resistance elements connected between opposite ends of the corresponding one of the plurality of transistors.

9. The memory device of claim 1, wherein the at least one memory cell is in a first region of the memory cell array, and wherein the value of the write voltage and the value of the reference resistance are stored in a second region of the memory cell array, the second region including a one-time programmable (OTP) memory.

10. A method of operating a memory device which includes a plurality of memory cells, the method comprising:
programming the plurality of memory cells to a first state;
counting first fail bits of the memory cells programmed to the first state using a plurality of resistances with different values, and outputting numbers of the first fail bits as first counting results;
programming the plurality of memory cells to a second state different from the first state;
counting second fail bits of the memory cells programmed to the second state using the plurality of resistances, and outputting numbers of the second fail bits as second counting results;
selecting a value of a reference resistance from among the plurality of resistances based on the first counting results and the second counting results;
programming the plurality of memory cells to the first state using a value of an initial write voltage corresponding to the reference resistance;
counting third fail bits of the memory cells programmed to the first state using the reference resistance and the value of the initial write voltage, and outputting a number of the third fail bits as a third counting result;
programming the plurality of memory cells to the first state using a second write voltage having a value different from the value of the initial write voltage;
counting fourth fail bits of the memory cells programmed to the first state using the reference resistance and the second write voltage, and outputting a number of the fourth fail bits as a fourth counting result; and
obtaining a value of a final write voltage based on the third counting result and the fourth counting result.

11. The method of claim 10, wherein selecting the value of the reference resistance comprises:
selecting, as the value of the reference resistance, a resistance value for which a sum of a number of the first fail bits and a number of the second fail bits is minimized.

12. The method of claim 11, further comprising:
storing the selected value of the reference resistance in the memory device.

13. The method of claim 10, comprising, based on the third counting result being more than a criteria value, selecting a value of the second write voltage to be smaller than the value of the initial write voltage.

14. The method of claim 10, comprising, based on the third counting result being less than a criteria value, selecting a value of the second write voltage to be greater than the value of the initial write voltage.

15. The method of claim 10, wherein each of the plurality of memory cells includes a magnetic tunnel junction element.

16. A memory device comprising:
a memory cell array including a first region and a second region, wherein the first region includes a cell string and a dummy cell string, and wherein the cell string includes a plurality of memory cells each including a magnetic tunnel junction element;
a voltage generator configured to generate a code value corresponding to a write voltage;
a write driver configured to store data in the memory cell array based on the code value;
a sense amplifier including a first input terminal to which a first end of the cell string is connected and a second input terminal to which a first end of the dummy cell string is connected through a reference resistance; and
a current source circuit configured to provide input currents to the sense amplifier,
wherein the second region is configured to store a value of the write voltage and use the write voltage to program at least one memory cell among the plurality of memory cells, and is configured to store a value of the reference resistance and use the reference resistance to distinguish between a parallel state and an anti-parallel state of the at least one memory cell, and
wherein the value of the write voltage is based on a value of an initial write voltage corresponding to the value of the reference resistance and a value of a final write voltage obtained based on the value of the initial write voltage.

17. The memory device of claim 16, wherein each of the plurality of memory cells includes:
a cell transistor including a first end connected to a source line and a gate electrode connected to a word line; and
the magnetic tunnel junction element, the magnetic tunnel junction element including a first end connected to a second end of the cell transistor and a second end connected to a bit line.

18. The memory device of claim 16, wherein the value of the final write voltage is determined based on a program operation using at least one voltage value different from the value of the initial write voltage and fail bit counting by a read operation.

19. The memory device of claim 18, wherein the program operation using the at least one voltage value different from the value of the initial write voltage and the read operation are performed in a linear search method or a binary search method.

20. The memory device of claim 16, wherein the second region includes a one-time programmable (OTP) memory.
